(19) United States
(12) Patent Application Publication
(10) Pub. No.: US 2025/0321297 A1
(43) Pub. Date: Oct. 16, 2025

(54) METHODS AND SYSTEMS TO DETECT THE MAGNETIC FLUX GENERATED BY A FLUX QUBIT

(71) Applicants: QILIMANJARO QUANTUM TECH, S.L, Barcelona (ES); INSTITUT DE FÍSICA D' ALTES ENERGIES, Barcelona (ES)

(72) Inventor: Pol Forn-Díaz, Ripollet (ES)

(21) Appl. No.: 18/861,053

(22) PCT Filed: Apr. 28, 2023
(86) PCT No.: PCT/EP2023/061405

§ 371 Date: Oct. 28, 2024

(30) Foreign Application Priority Data
Apr. 28, 2022 (EP) 22382411.1

(51) Int. Cl. G01R 33/035; G01R 15/18

(52) U.S. Cl. CPC G01R 33/0358; G01R 15/18

(57) ABSTRACT

A method, and a corresponding system, are disclosed for measuring a direction, and optionally also a magnitude, of current in a flux qubit. The method comprises providing a probe signal to a resonator circuit having a resonance frequency. The probe signal transmits through or reflects from the resonator circuit. Further, the resonator circuit comprises a superconducting loop interrupted by a first Josephson junction and by a second Josephson junction. The first Josephson junction and second Josephson junction are connected in parallel. The superconducting loop is positioned such that it is inductively coupled to the flux qubit. The method further comprises measuring the reflected probe signal that has reflected from the resonator circuit or, respectively, measuring the transmitted probe signal that has transmitted through the resonator circuit. The method also comprises, based on a difference, such as a phase difference or amplitude difference, between the probe signal and the reflected probe signal or, respectively, between the probe signal and the transmitted probe signal, determining the direction of current in the flux qubit.

### TECHNICAL FIELD

This disclosure relates to a method and system for measuring a direction of current in a flux qubit. In particular to such a method and system involving a resonator circuit comprising a superconducting loop interrupted by a first Josephson junction and by a second Josephson junction.

### BACKGROUND

Quantum mechanics has had a huge impact into many areas of science by providing a whole new mathematical framework that helped—and keeps helping—to enhance the knowledge of nature in a very accurate way. This theory is so powerful that its applications have soon reached the information science arena, giving rise to what could be—if not yet—a new technological revolution. Quantum effects have been recognized as a tool for computation that would not only help to keep up with Moore's law of chip scaling as transistors as small as one single atom are envisioned, but also to find a more general representation of computation than the one offered by the classical Turing machine.

With this promised enormous potential, proving quantum advantage in currently available and near-term quantum devices (NISQ devices) and developing the first real-world practical applications of quantum computing has become a race between large academic institutions and technological companies. Nevertheless, there is a strong focus on attaining such a quantum advantage from the universal computation point of view with the development of gate-based models of quantum computation. It is however unlikely that such quantum devices will be able to outperform classical machines, as the technological demands to implement error correction protocols required for these devices are expected to be out of reach for at least the next 10 years.

A different focus is to pursue the quantum advantage from a rather more practical perspective: thinking of NISQ devices as dedicated quantum optimizers for a reduced but important set of problems. It is the case that some of the most challenging issues industry faces are in fact related to finding effective solutions to large and complex optimization problems, from logistics and finance to chemistry and materials science. The common factor of all these problems is that they do not count for a solution that provides both accurate and fast results in a simultaneous manner. This not only increases the costs of the various implicated industries that have to deal with heavy and approximate methods of computation but also prevents them from developing new products due to the current intractability of some of these problems.

Quantum annealers are promising candidates to give solutions to these problems, see for example {Perspectives of quantum annealing: Methods and implementations; Philipp Hauke et al 2020 Rep. Prog. Phys.; Vol 83; 054401}. Quantum annealers are based on the adiabatic model of computation and therefore their technological demands in terms of error correction are not so high. Because of that, the development timescale is lower and first prototypes of quantum annealers are already being established in the market. However, no proof of quantum advantage has yet been demonstrated.

Practical problems of interest usually involve so-called cost functions with many local minima. Such problems are difficult to solve for classical algorithms. It is namely very difficult for classical algorithms to find the global minimum of a cost function having many local minima. However, it is believed that quantum annealing can perform this task well. A cost function can be described as an (Ising) Hamiltonian. At the same time, the Hamiltonian can be taken to describe a collection of interacting qubits. Also, according to the adiabatic theorem, in order to find the ground state of an Ising model, one can find the ground state by initializing the system in the ground state of an initial Hamiltonian H1. This can be performed in practice by preparing each qubit in the system in either one of two states. Then, the system is let go typically in the sense that no gate-based operations are performed on qubits. By nature, the system parameters will change such that the Hamiltonian changes gradually from H1 to H0, wherein H0 represent the solution, i.e. is the ground state of the Ising model. H0 can then be determined by reading out the states of the respective qubits.

For quantum annealing, the so-called coherence time of the qubits, which indicates how long a qubit retains its information, should be relatively long. In principle, the qubits should retain their information at least as long as the total time of computation. In other words, the evolution of the qubits should be primarily dictated by quantum mechanics throughout an annealing cycle. Without coherence, no quantum advantage is to be expected. Thus, there is a continuous strive in the art for improved coherence of qubits, in particular flux qubits which are very suitable as building blocks of quantum annealers.

Another important aspect of a quantum computer is the read-out of the qubits. In the context of quantum annealing using flux qubits, each flux qubit will be in either one of two states defined by the direction of the persistent current that is circulating through a loop of the flux qubit. At the end of the annealing run, the state of each flux qubit should be measured somehow. Reference {Exploring More-Coherent Quantum Annealing by Novikov et al; 12 Sep. 2018; 2018 IEEE International Conference on Rebooting Computing; DOI: 10.1109/ICRC.2018.8638625} proposes a read-out scheme that utilizes a resonator terminated by an rf-SQUID inductively coupled to a flux qubit using a switch. A disadvantage of this read-out scheme is that the resonance frequency of the rf-SQUID as a function of the flux through the qubits exhibits very sharp discrete jumps requiring additional decoupling circuitry between the qubit and the rf-SQUID resonator to ensure isolation of the qubit during the annealing phase. Additional disadvantages of this read-out scheme are that it requires quite a number of control lines (which is undesired as they may be a source of noise and male the system more costly) and calibration of multiple circuit elements is necessary which require control of various fluxes quite accurately in the time domain.

In light of the above, there is a need in the art for methods and systems for reading out flux qubits that alleviate at least some of the drawbacks identified above.

### SUMMARY

To that end, a method is disclosed for measuring a direction, and optionally also a magnitude, of current in a flux qubit. The method comprises providing a probe signal to a resonator circuit having a resonance frequency. The probe signal transmits through or reflects from the resonator circuit. Further, the resonator circuit comprises a superconducting loop interrupted by a first Josephson junction and by a second Josephson junction. The first Josephson junction and the second Josephson junction are connected in parallel. The superconducting loop is inductively coupled to the flux qubit. The method further comprises measuring the reflected probe signal that has reflected from the resonator circuit or, respectively, measuring the transmitted probe signal that has transmitted through the resonator circuit. The method also comprises, based on a difference, such as a phase difference or amplitude difference, between the probe signal and the reflected probe signal or, respectively, between the probe signal and the transmitted probe signal, determining the direction of current in the flux qubit.

Also, a system is disclosed for measuring a direction of current in a flux qubit. The system comprises a resonator circuit having a resonance frequency. The resonator circuit comprises a superconducting loop interrupted by a first Josephson junction and by a second Josephson junction. The first Josephson junction and second Josephson junction are connected in parallel. Further, the superconducting loop is positioned such that it is inductively coupled to the flux qubit. The system further comprises a probe signal provisioning system for providing a probe signal to the resonator circuit such that the probe signal transmits through or reflects from the resonator circuit. The system also comprises a measurement system for measuring the reflected probe signal that has reflected from the resonator circuit or, respectively, for measuring the transmitted probe signal that has transmitted through the resonator circuit. The system further comprises a probe signal analysis system for determining a difference between the probe signal and the reflected probe signal or, respectively, between the probe signal and the transmitted probe signal.

The methods and systems disclosed herein for measuring the direction of current in a flux qubit may be understood as methods and systems for reading out the flux qubit. The method is for example implemented after an annealing cycle has been performed. As is known, at the end of an annealing cycle, in which the involved flux qubits are maintained in their respective ground states, each flux qubit will be in a well-defined persistent current state. In particular, the current in each flux qubit will have a clockwise direction or a counter-clockwise direction. At the end of the annealing cycle, each state, i.e. each current direction, should be measured. In other words, at the end of the annealing cycle, each flux qubit should be “read out”. Of course, while the direction of current in the flux qubit is directly related to the magnetic flux generated by the flux qubit, the methods and systems disclosed herein may also be understood as methods and systems for measuring the magnetic flux generated by a flux qubit.

The inventors have found that such a method and system enable to accurately measure, in a convenient manner, the direction of current in a flux qubit. Depending on whether current in the flux qubit has a clockwise direction or counter-clockwise direction, the magnetic flux generated by the flux qubit will have either a first direction, e.g. a downwards direction, or a second direction, e.g. an upwards direction. Since the flux qubit is inductively coupled to the superconducting loop, which may be referred to as a DC-SQUID (direct current-superconducting quantum interference device), the flux threading the superconducting loop changes. This, in turn, causes a change of the resonant frequency of the resonator circuit. Further, depending on the resonance frequency at the time when the electromagnetic probe signal is provided to the resonator circuit, the probe signal will experience a different phase and/or amplitude shift. To illustrate it, if the resonant frequency of the resonator circuit matches the frequency of the probe signal, then the resonator circuit will absorb most of the probe signal. However, if the resonance frequency is different from the frequency of the probe signal, then much of the probe signal will be transmitted/reflected. Also, if the probe signal has a different frequency than the resonant frequency of the resonator circuit, the transmitted/reflected probe signal will be phase- and amplitude-shifted relative to the provided probe signal. Whether the phase shift is positive or negative depends on whether the frequency of the provided probe signal is higher or lower than the resonant frequency. This phase-shifting, as will be explained in more detail below, can also be used for determining the direction of the current in the flux qubit. In any case, based on a difference between the provided probe signal and the reflected/transmitted probe signal can the resonant frequency of the resonator circuit be determined, which in turn enables determination of the current direction in the flux qubit. The methods described herein for measuring the direction of current in a flux qubit can additionally or alternatively be used for determining the magnitude of the current in a flux qubit. In principle, a flux magnitude change will also change the flux threading the DC-SQUID resonator, which induces the same chain of effects as described above.

The use of the DC-SQUID type resonator for readout of a flux qubit provides substantial advantages to known readout schemes in which for example an rf-SQUID type resonator is used for readout. The DC-SQUID type resonator can be biased with flux to be sensitive or insensitive for small flux changes. This may be used to effectively couple or decouple the qubit from the resonator. Thus, when an algorithm is executed (i.e. annealing is performed) the DC-SQUID may be biased to a flux-insensitive point not sensing any flux from the qubit, and, vice-versa, the DC-SQUID does not couple flux into the qubit. The qubit is effectively decoupled from the SQUID resonator at this flux operation point, preventing noise from the readout lines connected to the SQUID not reaching the qubit. This way the coherence time can be kept as long as possible. Once the algorithm is finished (annealing finished), the SQUID may be set to an operation point to perform the readout. At this operation point, the SQUID is sensitive to flux and therefore senses the additional flux generated by the qubit. The readout operation of the qubit current state needs to be performed fast enough to avoid noise coming from the SQUID readout line to affect the qubit coherence. This guarantees maximum readout visibility.

In an embodiment, the resonator circuit may be controlled to be a first state or in a second state, wherein in the first state the resonator circuit is insensitive to flux so that it decouples from the flux qubit and wherein in the second state the resonator circuit is sensitive to flux so that it is coupled to the flux qubit for determining the direction of the current in the flux qubit.

In an embodiment, the resonator circuit may be controlled to be in the first state based on a first flux signal or to be in the second state using a second flux signal.

Preferably, the resonator circuit comprises a capacitor other than the junction self-capacitance. Preferably, such a capacitor and the first and/or second Josephson junction would be connected in parallel. Such a capacitor may also be referred to as a shunt capacitor. As referred to herein, two or more components being connected in parallel may be understood as that each has the same potential difference, voltage, across their ends. Thus, preferably, the first Josephson junction, second Josephson junction, and capacitor each have the same voltage across their ends.

In principle, the coupling between the superconducting loop and the flux qubit should be strong enough such that the change in Josephson inductance of the resonator circuit and the associated change of the resonant frequency is large enough so that it can be detected by determining a difference between a provided probe signal and a transmitted/reflected probe signal. For a symmetric DC-SQUID, the fractional frequency change is df/f₀=(π/2)tan(πΦ/Φ₀)dΦ/dΦ₀. Using typical values, this fractional change is in the 10⁻³ range, which corresponds to a change of several MHz for a GHz resonator. This formula also makes it explicit that when the flux in the DC-SQUID is set to 0 (Φ=0), no fractional change in the SQUID resonator frequency can be detected coming from the qubit.

The method disclosed herein for measuring the state of the flux qubit may be understood to be a so-called dispersive measurement. The signal required to perform the readout which is close to the resonator frequency is very far detuned from the qubit, and hence cannot induce transitions of the qubit state. The impact of the read-out on the flux qubit itself is thus very low. Further, such dispersive read-out method obviates the need to add resistors to the superconducting circuitry, which would add thermal noise to the system and decrease the coherence time of the qubit.

A flux qubit, which may also be referred to as a persistent current qubit, comprises a superconducting loop that is interrupted by at least one Josephson junction. Typically, the superconducting loop of the flux qubit is interrupted by three Josephson junctions, two of which have identical Josephson energies E_{J} while the third one has a smaller Josephson energy αE_{J}. Usually, α>0.5 so that the potential energy of the flux qubit has two wells corresponding to two ground state configurations when the flux in the qubit loop is near Φ₀/2. Due to quantum tunneling, the two ground state configurations hybridize in a unique ground state which is a superposition of the two wells. Typically, a has a value in the range 0.6-0.7. Typically, a flux qubit is “driven” by providing a flux to the flux qubit using an external flux generating circuit. The provided flux then threads the qubit loop of the flux qubit. Herewith, for example, the frustration f of the qubit may be set. The frustration f of a flux qubit may be defined as

$$f = ( {Φ}_{q b} - ( n + \frac{1}{2} ) {Φ}_{0} ) / {Φ}_{0} ,$$

wherein φ_{qb} is the flux provided to the qubit loop (by the external flux generating element), n is an integer, Φ₀=h/2e is the flux quantum. Note that this frustration is defined relative to the so-called symmetry point corresponding to Φ₀/2+n. Preferably, the flux qubits described herein are not driven such that Φ_{qb}=0. At Φ_{qb}=0, the flux qubit has a single potential well and namely does not generate a net magnetic flux that can be measured using the DC-SQUID readout method presented here.

The resonant frequency of the resonator circuit may be higher than the qubit frequency, which corresponds to the energy difference between the qubit ground state and its first excited state. The resonant frequency of the resonator circuit may be between 5-9 GHz, preferably between 6-8 GHz. Such relatively high resonant frequencies decrease the probability to thermally excite photons in the resonator mode that would induce noise in the qubit. If the resonator circuit would have a relatively low resonant frequency, such as 1 GHZ, then it may get thermally excited, which will distort the qubit. The probe signal may correspond to a coherent microwave signal.

Preferably, the probe signal has a power such that the resonator circuit operates in the linear regime when it is driven by the probe signal. This not only limits the amount of power that is required for reading out the flux qubit, it also eases the calibration requirements, because less parameters need to be optimized versus the case when high power probe signals are used. When a high-power probe signal would be used to probe the resonator circuit, which causes the resonator circuit to operate in the non-linear regime when it interacts with the probe signal, the amplitude and the frequency of the probe signal would have to be accurately tuned, because the available parameter space to discriminate the two qubit states is very narrow. Irrespective of the above, it should be appreciated that the probe signal may be configured with low enough power such that the resonator circuit does not exhibit hysteresis during the measurement.

Preferably, the probe signal provided to the resonator circuit for reading out the flux qubit is a pulsed signal as opposed to a continuous signal. Typical length of the pulse is 0.5-1 microseconds. However, if an amplifier is implemented (see below) then the pulse may be as short as 100 ns or even shorter. Irrespective of this, preferably, the method does not comprise continuously providing an AC signal to the resonator circuit, as this would produce noise on the qubit and thus decrease its coherence time.

Types of Josephson junction include the @ Josephson junction (of which IT Josephson junction is a special example), long Josephson junction, and superconducting tunnel junction. It should be appreciated that the Josephson junctions described herein are operated below their respective critical Josephson currents, i.e. below the maximum supercurrent that each junction can sustain. A Josephson junction may be formed by a combination of two or more sub-Josephson junctions, e.g. when two sub-Josephson junctions are connected in parallel and interrupt a superconducting loop as a so-called compound Josephson junction.

In an embodiment, the method comprises providing, using a flux generating circuit that is inductively coupled to the superconducting loop of the resonator circuit, a magnetic flux to the superconducting loop herewith controlling the resonant frequency of the resonator circuit. In an embodiment, the system comprises a flux generating circuit that is inductively coupled to the superconducting loop of the resonator circuit and that is configured to provide a magnetic flux to the superconducting loop for controlling the resonant frequency of the resonator circuit.

This embodiment enables to control the resonant frequency to have a desired and/or appropriate value. In this embodiment, the resonator circuit the first Josephson junction and second Josephson junction act as a flux-tunable inductor, also referred to as the Josephson inductance of the resonator circuit. In particular, this embodiment enables to set the DC SQUID of the resonator circuit in a flux sensitive point close to the Φ₀/2 flux through the DC SQUID loop, meaning that a relatively small change in flux through the DC SQUID causes a relatively large change in the resonant frequency of the resonator circuit.

The flux generating circuit referred to above is not the flux qubit, of course, and may therefore also be referred to as an “external” flux generating circuit.

The first Josephson junction has a first critical current value and the second Josephson junction has a second critical current value. The second critical current value may be different from the first critical current value. The two Josephson junctions may thus have different critical current values. As known in the art, a critical current value for a Josephson junction indicates the maximum supercurrent that can run through the Josephson junction in question.

The first and second Josephson junctions having different critical current values may be referred to as that Josephson junctions are asymmetric. The asymmetry between junctions in a DC-SQUID normally reduces the sensitivity for the same flux as compared to the symmetric case. However, the asymmetry has a second effect: a change in flux in the DC-SQUID loop effectively induces an offset in the superconducting phase across the DC-SQUID, which is equivalent to current-biasing the DC-SQUID. Such a phase bias additionally modifies the DC-SQUID inductance, thus providing an overall increased sensitivity. The theory behind this is as explained in more detail with reference to FIG. 5.

In the context of the resonator circuit, in particular of the DC-SQUID of the resonator circuit, a bias current provided to the resonator circuit, in particular to the DC-SQUID, may be understood to refer to the current that flows through the DC-SQUID, i.e. the current that enters and exits the DC-SQUID as opposed to a (persistent) current circulating the DC-SQUID loop. Such circulating current may be caused by flux provided by the external flux generating circuit described above.

In an embodiment, the method may comprise providing a bias current, preferably a DC bias current, to the resonator circuit, in particular to the superconducting loop that is interrupted by the first and second Josephson junction. In an embodiment, the system may comprise a bias current provisioning system for providing such bias current to the resonator circuit, in particular to the superconducting loop that is interrupted by the first and second Josephson junction.

In an embodiment of the method and in an embodiment of the system, the resonator circuit comprises a second superconducting loop that is interrupted by the second Josephson junction. In such a case, the method may comprise using a second flux generating circuit that is inductively coupled to the second superconducting loop of the resonator circuit, to provide a magnetic flux to the second superconducting loop for biasing the first superconducting loop with a bias current, preferably with a DC bias current. Likewise, in such a case, the system may comprise a second flux-generating circuit that is inductively coupled to the second superconducting loop of the resonator circuit, and that is configured to provide a magnetic flux to the second superconducting loop for biasing the first superconducting loop with a bias current, preferably with a DC bias current.

In an embodiment, the second flux generating circuit may be configured provide a first magnetic flux value to the second superconducting loop so that the resonator is insensitive to flux and therefore decouples from the flux qubit, when the flux qubit is being operated, or to provide a second flux value to the second superconducting loop so that the resonator is sensitive to flux when the current direction of the flux qubits needs to be determined.

In case the resonator circuit comprises a second superconducting loop as described above, then, preferably, the superconducting loop that is interrupted by the first and second Josephson junctions, also referred to as the DC-SQUID, is inductively coupled stronger to the flux qubit than the second superconducting loop, e.g. in the sense that the DC-SQUID is positioned closer to the flux qubit than the second superconducting loop.

As will be explained in more detail below this embodiment renders the resonator circuit more sensitive to flux changes. Hence, the accuracy of determining the direction of current in the flux qubit is improved.

Due to the inductive coupling between the superconducting loop and the flux qubit, the resonant frequency of the resonator circuit has a first value when the current in the flux qubit has a first direction, e.g. a clockwise direction, and has a second value, different from the first value, when the current in the flux qubit has a second direction, e.g. a counter-clockwise direction. Preferably, the probe signal provided to the resonator circuit has a frequency lower than the first or second value and higher than the second or, respectively, first value.

This embodiment is advantageous in that, depending on whether the current in the flux qubit is clockwise or counter-clockwise, the probe signal will have a lower or higher frequency than the resulting resonant frequency of the resonator circuit as a result of which the phase shift of the transmitted/reflected probe signal relative to the provided probe signal is either positive or negative. Whether, given a current direction in the flux qubit, the phase shift is positive or negative depends on whether the DC-SQUID is flux-biased at a positive slope or negative slope. (See FIG. 6, for example.) Therefore, it would be sufficient to only determine the sign of the phase shift because that already allows to determine the current direction in the flux qubit based on this method.

In an embodiment, the probe signal is provided to the resonator circuit via a probe line, also referred to as a read-out line. In this embodiment, the method comprises preventing noise signals arriving via the probe line from reaching the resonator circuit using a bandpass filter, such as a resonator filter, also known in the literature as Purcell filter.

In an embodiment, the system comprises a bandpass filter, preferably a resonator filter, such as a Purcell filter, that is configured to prevent noise signals, that come from a probe line via which the probe signal is provided to the resonator circuit, from reaching the resonator circuit. The system may comprise this probe line.

Preferably, a Purcell filter is positioned between the resonator circuit and the read-out line, e.g. as depicted in FIG. 1 of this application. Typically, the Purcell filter is a capacitor and inductor connected in parallel thus forming an LC resonator.

The Purcell filter protects the resonator circuit, and thus also the qubit from noise coming from the read-out line. The qubit frequency is below the frequency of the resonator circuit and also below the passband of the bandpass filter. Preferably, the bandpass filter is centered around the resonant frequency of the resonator circuit in order to improve signal transfer between the resonator circuit and bandpass filter. Hence, the flux qubit is doubly protected, by the resonator circuit and by the bandpass filter. Further, the passive Purcell filter obviates the need for implementing active switches for coupling and decoupling the flux qubit to a read-out circuit. This reduces the number of required control lines, which may be a source of noise, but, in any case, simplifies design and fabrication.

On one hand the qubit frequency and the resonant frequency of the resonator circuit are close to each other because that improves the signal from the flux qubit. However, on the other hand, the qubit frequency and the resonant frequency being close to each other also enhances the Purcell effect, which limits the qubit lifetime. The bandpass filter enables to set the qubit frequency closer to the resonant frequency of the resonator circuit without reducing the lifetime of the qubit significantly. The reason is that the bandpass filter attenuates the noise at the qubit frequency entering the readout resonator from the readout line.

Preferably, the bandpass filter has a relatively low quality factor for fast read-out or, in other words, for low response times. The response time of the bandpass filter namely goes as ˜Q/w, where Q is the external quality factor of the bandpass filter determined by its coupling to the readout line. A lower Q means a shorter response time. The bandpass of the filter is typically a few MHz broad.

To illustrate this, given a resonator circuit having a resonant frequency in the GHz range, since the bandpass filter is preferably resonant with the resonator circuit, its passband is preferably centered in the GHz range, while the bandwidth corresponds to a Q of 50-100, so a few MHz which corresponds to a few (10-20) nanoseconds response time.

In an embodiment, the method comprises, after bandpass filtering the reflected or transmitted probe signal, amplifying the reflected or transmitted probe signal using a quantum-limited amplifier, such as a traveling-wave parametric amplifier. In an embodiment the system comprises a quantum-limited amplifier that is configured to amplify the transmitted or reflected probe signal. Preferably, the amplification by the amplifier is performed after the probe signal has reflected from/transmitted through the {band-pass filter+SQUID resonator} system

The inventors have found that the amplifier significantly increases the readout contrast. The amplifier may be an independent circuit, e.g. in the sense that it sits on a separate chip. The combination of resonator filter and amplifier yields high readout contrast in a short timescale. The resonator filter allows to use fast readout and therefore to use advanced techniques like feedback. Feedback is for example used when all qubits should be initialized in their ground state (as is the case in annealing) by reading out their state to discard faulty runs when one of the qubits was found in its excited state, as it may spontaneously happen due to thermal fluctuations.

In an embodiment, at least part of the system is in a cryogenic environment. In such a case, said at least part of the system in the cryogenic environment does not comprise a resistor.

Advantageously, the method and system do not require resistors in the cryogenic environment, for example to measure voltages. Hence, distortion from such dissipative elements is no issue.

Preferably, the system does not comprise a resistor between the resonator circuit and the bandpass filter. Preferably, the system does not comprise a resistor between the resonator circuit and the read-out line.

The system may comprise a read-out line that connects room-temperature electronics to the cryogenic environment of a quantum circuit. Preferably, no resistors are present between the resonator circuit and the read-out line.

In an embodiment, the system comprises a data processing system that is configured to, based on the difference between the probe signal and the reflected probe signal or, respectively, between the probe signal and the transmitted probe signal, such as a phase difference, determining the current direction in the flux qubit.

One aspect of this disclosure relates to a chip comprising any of the systems—as described herein—for measuring a direction of current in flux qubit.

One aspect of this disclosure relates to a computer comprising a
a computer readable storage medium having computer readable program code embodied therewith, and
a processor, preferably a microprocessor, coupled to the computer readable storage medium, wherein responsive to executing the computer readable program code, the processor is configured to perform any of the methods described herein.

One aspect of this disclosure relates to a computer program or suite of computer programs comprising at least one software code portion or a computer program product storing at least one software code portion, the software code portion, when run on a computer system, being configured for executing any of the methods described herein.

One aspect of this disclosure relates to a non-transitory computer-readable storage medium storing at least one software code portion, the software code portion, when executed or processed by a computer, is configured to perform any of the methods described herein.

As will be appreciated by one skilled in the art, aspects of the present invention may be embodied as a system, a method or a computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Functions described in this disclosure may be implemented as an algorithm executed by a processor/microprocessor of a computer. Furthermore, aspects of the present invention may take the form of a computer program product embodied in one or more computer readable medium(s) having computer readable program code embodied, e.g., stored, thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples of a computer readable storage medium may include, but are not limited to, the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of the present invention, a computer readable storage medium may be any tangible medium that can contain, or store, a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber, cable, RF, etc., or any suitable combination of the foregoing. Computer program code for carrying out operations for aspects of the present invention may be written in any combination of one or more programming languages, including an object oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems), and computer program products according to embodiments of the present invention. It will be understood that each block of the flowchart illustrations and/or block diagrams, and combinations of blocks in the flowchart illustrations and/or block diagrams, can be implemented by computer program instructions. These computer program instructions may be provided to a processor, in particular a microprocessor or a central processing unit (CPU), of a general purpose computer, special purpose computer, or other programmable data processing apparatus to produce a machine, such that the instructions, which execute via the processor of the computer, other programmable data processing apparatus, or other devices create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

Moreover, a computer program for carrying out the methods described herein, as well as a non-transitory computer readable storage-medium storing the computer program are provided. A computer program may, for example, be downloaded (updated) to the existing systems or be stored upon manufacturing of these systems.

Elements and aspects discussed for or in relation with a particular embodiment may be suitably combined with elements and aspects of other embodiments, unless explicitly stated otherwise. Embodiments of the present invention will be further illustrated with reference to the attached drawings, which schematically will show embodiments according to the invention. It will be understood that the present invention is not in any way restricted to these specific embodiments.

### BRIEF DESCRIPTION OF THE DRAWINGS

Aspects of the embodiments will be explained in greater detail by reference to exemplary embodiments shown in the drawings, in which:

FIG. 1 illustrates a system 1 for measuring a direction of current in a flux qubit according to an embodiment;

FIG. 2A is a flow chart illustrating a measurement method according to an embodiment;

FIG. 2B is a schematical representation of a DC-SQUID;

FIG. 3 illustrates a system according to an embodiment comprising a second superconducting loop for current biasing the DC-SQUID;

FIG. 4 is a graph showing biasing current against the flux threading the second superconducting loop;

FIG. 5 is an embodiment comprising an asymmetric DC-SQUID;

FIG. 6 is a graph showing resonance frequency versus flux through the DC-SQUID;

FIG. 7 is an embodiment comprising an asymmetric DC-SQUID and a second superconducting loop for current biasing the DC-SQUID;

FIG. 8 illustrates a coupling system for coupling flux qubits;

FIG. 9 illustrates a system according to an embodiment;

FIG. 10 illustrates a data processing system according to an embodiment.

### DESCRIPTION OF THE EMBODIMENTS

In the figures, identical reference numbers indicate identical or similar elements.

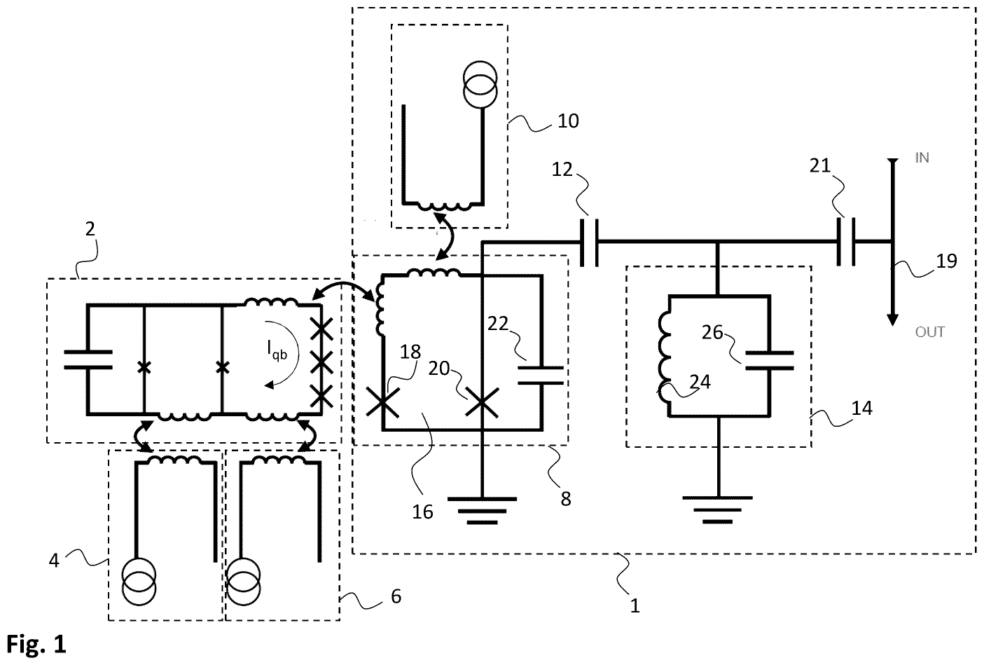

FIG. 1 illustrates a system 1 for measuring a direction of current I_{qb} in a flux qubit 2. In the depicted embodiment, the flux qubit 2 comprises five Josephson junctions. The depicted flux qubit 2 is biased by a flux generating circuit 4 in the sense that the so-called X-loop of the flux qubit 2 is inductively coupled to flux generating circuit 4 and in that a magnetic flux generated by the flux generating circuit 4 threads the X-loop of the flux qubit 2. Similarly, the depicted flux qubit 2 is also biased by flux generating circuit 6 in the sense that the so-called main loop of the flux qubit 2, also referred to as the Z-loop, is inductively coupled to flux generating circuit 6. The X-loop is in fact a DC-SQUID that effectively determines the size of the small qubit junction, so-called a-junction, which controls the minimum qubit energy splitting, known as the qubit gap. The Z-loop determines the magnetic energy of the qubit, it determines its flux operating point as well as its resonance frequency. However, the methods and systems disclosed herein enable to measure the current direction in any type of flux qubit.

In the depicted embodiment, the system 1 comprises a resonator circuit 8, a flux generating circuit 10, a first capacitor 12, a resonator-based bandpass filter 14, a second capacitor 16 and read-out circuitry 19, such as a read-out line. The resonator circuit has a resonance frequency and comprises a superconducting loop 16 interrupted by a first Josephson junction 18 and by a second Josephson junction 20. The Josephson junctions 18 and 20 are connected in parallel. The superconducting loop 16 comprising the parallel connected Josephson junction may also be referred to as a DC-SQUID. Loop 16 is positioned such that it is inductively coupled to the flux qubit 2. In particular, loop 16 is directly coupled to the flux qubit via inductive coupling, without any intermediate coupling circuit between the flux qubit and the resonator. As a result, the flux threading the loop 16 depends on the flux generated by the flux qubit, which, in turn, depends on the direction of the current I_{qb}. flowing in the flux qubit 2, in particular through the main loop.

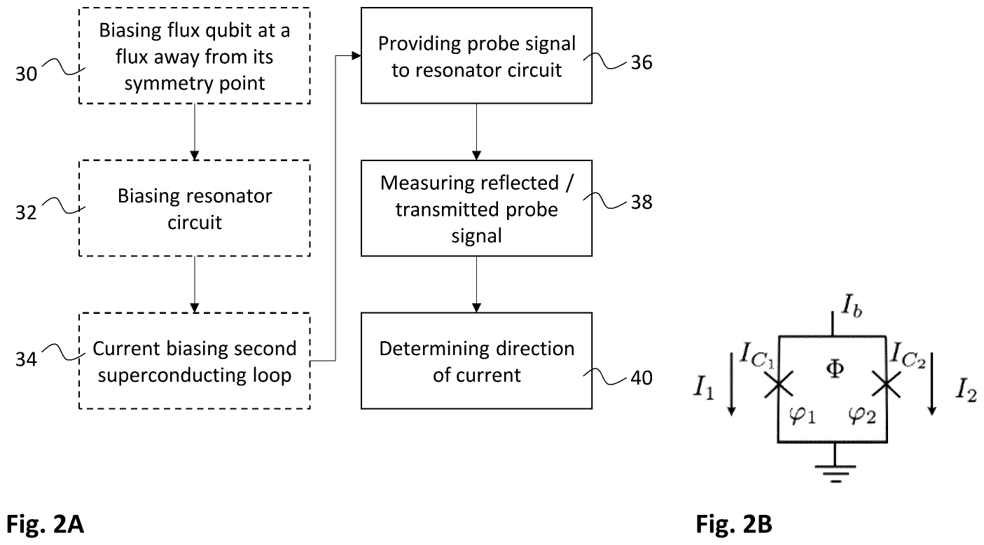

In general, a DC-SQUID can be modelled as two Josephson junctions in parallel, each with its own critical current I_{C}. A magnetic flux Φ threads the DC-SQUID (see FIG. 2B). Each junction has a superconducting phase across it φ that determines the current through it using the first Josephson relation:

$$I = {I}_{C} sin ( φ )$$

The two phases of the junctions in a DC-SQUID are related to each other because of the quantum mechanical property of phase quantization, in which the total phase around a superconducting loop has to be an integer number of 2π, due to the wavefunction being single valued (that is, it can only have one value at each point of the loop, irrespective of the amount of turns one does around the loop). Any external magnetic flux threading the loop will add to the total phase around the loops such that:

$${\sum }_{i}^{N} {φ}_{i} = 2 π \frac{Φ}{{Φ}_{0}}$$

wherein

$${Φ}_{0} = \frac{h}{2 e} = 2.07 \times 1 {0}^{- 15} Wb$$

is the flux quantum. For the DC-SQUID, this becomes:

$${φ}_{1} - {φ}_{2} = 2 π f$$

where f is the frustration f=Φ/Φ₀. The resonator circuit 8 can be considered as an inductor Lⱼ in parallel to the capacitor 22. The value of the inductance depends on the flux Φ threading the DC-SQUID 16. In general, the inductance is given by:

$${L}_{J} = \frac{{Φ}_{0}}{2 π I ( Φ ) cos ( φ )}$$

wherein I(Φ) indicates the critical current for flux Φ, Φ₀ is the flux quantum Φ₀=h/(2e)=2.07×10⁻¹⁵Wb, and φ the phase difference of the superconducting wave across the DC-SQUID. The phase difference directly relates to the bias current.

A symmetric DC-SQUID, wherein the first and second Josephson junctions have the same critical current value, has the following Josephson inductance:

$${L}_{J}^{S} = \frac{{Φ}_{0}}{2 π ( 2 {I}_{C} ) cos ( π f ) cos ( {φ}_{D C} )} .$$

Here, f≡Φ/Φ₀, φ_{DC}≡arcsin (I_{B}/I_{C}(Φ) where I_{B} is a bias current through the DC-SQUID. The DC-SQUID critical current is:

$${I}^{s} ( Φ ) = 2 I\_C \vert cos ( φ f ) \vert ,$$

such that the supercurrent through it is:

$$I = {I}^{S} ( Φ ) sin φ$$

Here, the phase is the sum of the phase of each junction. The DC-SQUID resonance frequency corresponds to that of an LC circuit,

$${ω}_{SQ} = {( {L}_{J}^{S} C )}^{- 1 / 2} .$$

A change in flux δΦ coming from the flux qubit will produce a change in resonance frequency δω as follows (equation A):

$$δω = \frac{\partial {ω}_{SQ}}{\partial Φ} δΦ = \frac{\partial {ω}_{SQ}}{\partial {L}_{J}^{S}} \frac{\partial {L}_{J}^{S}}{\partial Φ} δΦ = - {ω}_{SQ} \frac{π}{2} tan ( π f ) \frac{δΦ}{{Φ}_{0}} .$$

The system 1 further comprises a probe signal provisioning system for providing a probe signal to the resonator circuit 8 such that the probe signal transmits through or reflects from the resonator circuit 8. In the depicted embodiment, the signal provisioning system may be understood to be formed by the probe signal input line 19 that conduct the probe signal to the resonator circuit 8.

The system 1 also comprises a measurement system (not shown) for measuring the reflected probe signal that has reflected from the resonator circuit 8 or, respectively, for measuring the transmitted probe signal that has transmitted through the resonator circuit 8, and a signal analysis system (not shown) for determining a difference between the provided probe signal and the reflected probe signal or, respectively, between the provided probe signal and the transmitted probe signal.

The measurement system typically comprises a heterodyning setup in which the probe signal is first split, with one half of the signal probing the resonator 8. The other half is used as reference that is re-combined with the reflected/transmitted probing signal in a frequency mixer, where it is downconverted to an intermediate frequency in the MHz range that is digitized by a data acquisition system such as an FPGA (field programmable gate array) or an ADC (analog-to-digital converter) as in an oscilloscope. The phase difference can then be extracted from the digitized signal.

The flux generating circuit 10 is inductively coupled to the superconducting loop 16 of the resonator circuit 8 and is configured to provide a magnetic flux to the superconducting loop 16 for controlling the resonant frequency of the resonator circuit 8, which at the same time determines the resonator sensitivity to magnetic flux.

The bandpass filter 14, preferably a Purcell filter, is configured to prevent noise signals from reaching the resonator circuit 8, and thus from reaching the flux qubit 2. The noise signals come from the probe line 19 via which the probe signal is provided to the resonator circuit 8. Typically, the bandpass filter comprises an inductor 24 connected in parallel to a capacitor 21.

Preferably, the system also comprises a quantum-limited amplifier that is configured to amplify the transmitted or reflected probe signal.

At least part of the system is in a cryogenic environment and wherein said at least part of the system in the cryogenic environment does not comprise a resistor. To illustrate, in the depicted embodiment, no resistor is present between resonator circuit 8 and read out line 18.

FIG. 2A is a flow chart illustrating a measurement method according to an embodiment. Herein, the steps 30, 32, 34 are optional.

Step 30 comprises biasing the flux qubit at a flux away from its symmetry point. This ensures that indeed the flux qubit generates a magnetic flux that can be picked up by the DC-SQUID. The flux qubit is biased at a given flux at the end of the annealing run and is subsequently read-out.

Preferably, throughout the measurement method described herein, the flux qubit is maintained in its ground state. Such maintaining in the ground state may for example be performed by refraining from providing any signal to the qubit that causes the flux qubit to transition to an excited state. When performing quantum annealing, the qubits may do excursions to excited states, but they will always be brought back to the ground state.

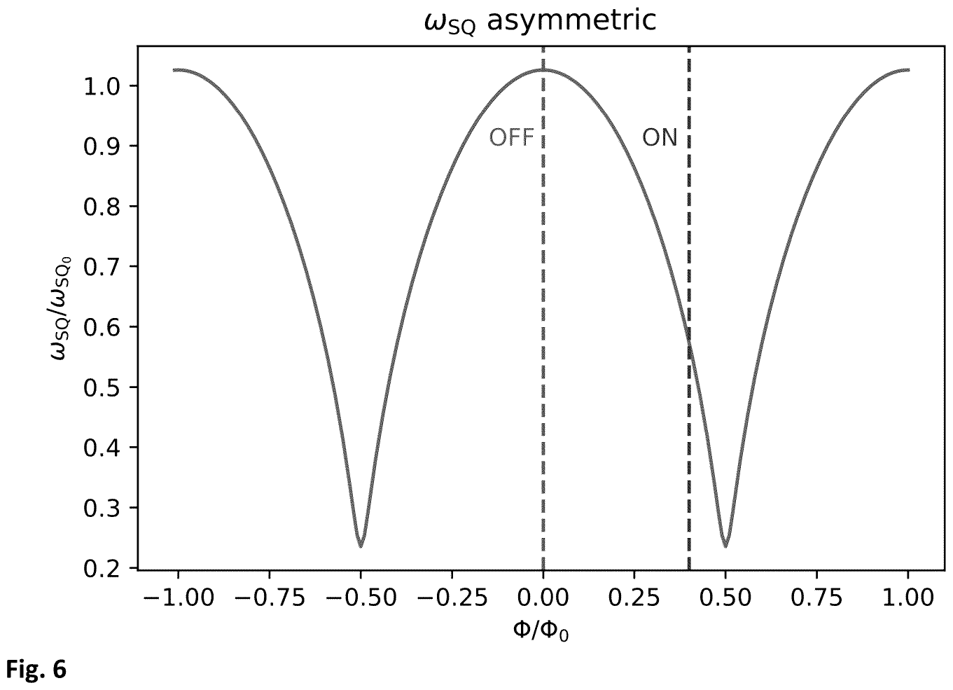

Step 32 comprises providing a magnetic flux to the DC-SQUID in order to control the resonant frequency of the resonator circuit. As will be explained below with reference to FIG. 6, preferably, when an algorithm is executed (annealing is performed) the DC-SQUID is biased to a flux-insensitive point, where small flux changes threading the DC-SQUID will not cause changes in the resonant frequency of the resonator circuit. In this case, the qubit is effectively isolated from the resonator circuit. In contrast, during readout (after execution of the algorithm, the DC-SQUID is biased to a flux-sensitive point, where relatively small changes in the flux threading the DC-SQUID cause a relatively large change in resonant frequency of the resonator circuit 8.

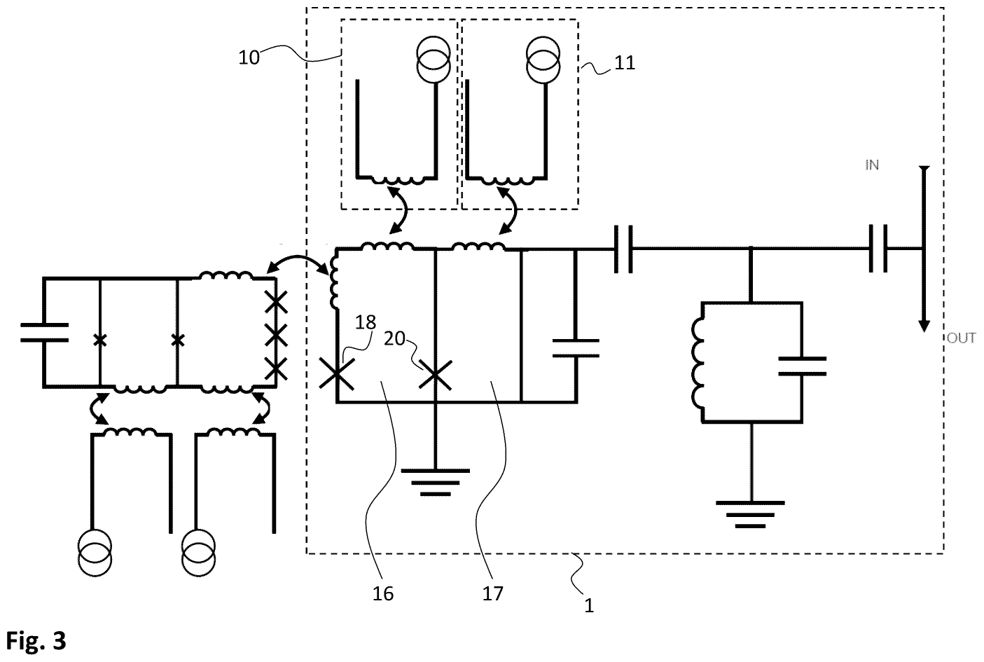

Step 34 comprises providing a bias current, preferably a DC bias current, to the resonator circuit 8, in particular to the DC-SQUID. FIG. 3 depicts a system according to an embodiment that is configured to provide such bias current to the DC-SQUID using an additional loop 17 and a second flux generating circuit 11.

Steps 36 comprises providing a probe signal to a resonator circuit, step 38 measuring the reflected probe signal that has reflected from the resonator circuit or, respectively, measuring the transmitted probe signal that has transmitted through the resonator circuit, and step 40 comprises, based on a difference, such as a phase difference or amplitude difference, between the provided probe signal and the reflected probe signal or, respectively, between the provided probe signal and the transmitted probe signal, determining the direction of current in the flux qubit.

FIG. 3 illustrates an embodiment that is similar to the embodiment of FIG. 1. Reference numbers are not shown for clarity. In this embodiment, the resonator circuit 8 comprises a second superconducting loop 17 that is interrupted by the second Josephson junction 20. Further, in the depicted embodiment, the first 18 and second 20 Josephson junctions have equal critical current values. The system also comprises a second flux generating circuit 11 that is inductively coupled to the second superconducting loop 17 of the resonator circuit 8. Flux generating circuit 11 is configured to provide a magnetic flux to the second superconducting loop 17 for biasing the first superconducting loop 16 with a bias current, preferably with a DC bias current. This bias current may be applied prior to the qubit measurement to an optimal bias point in which the noise from the SQUID circuit going to the qubit loop is minimized.

In general, the method and system disclosed herein allow to determine whether a flux qubit is in a first ground state configuration, in which the current circulates e.g. clockwise through the flux qubit, or in a second ground state configuration, in which the current circulates counter-clockwise through the flux qubit. The interaction between the qubit and the DC-SQUID is not of the electric-dipole type as is typical in dispersive measurements, but is through the nonlinear response of the DC-SQUID to magnetic fields. Nevertheless, it is possible to express it in the form of a dispersive Hamiltonian. The potential energy of the DC-SQUID is given by:

$${U}_{SQ} = - {E}_{J} ( Φ ) cos ( φ ) ,$$

where E_{J}(Φ)=(Φ₀/2π)I_{C}(Φ) is the flux-dependent Josephson energy, and I_{C}(Φ) is the critical current. The supercurrent through the DC-SQUID is:

$${I}_{s} = {I}_{C} ( Φ ) sin ( φ ) .$$

wherein I_{S} refers to external current supplied to the DC-SQUID. Note that in this disclosure, this external current may also be referred to as the bias current I_{B}. This external current may thus be provided by the second superconducting loop 17 biased with a flux from flux generating circuit 11.

The above equation connects the external current supplied to the SQUID I_{S} with the superconducting phase across the DC-SQUID, φ. For a fixed I_{S} and Φ, φ gets determined by this equation.

When a flux-like qubit couples to the DC-SQUID, it produces an additional flux do through the DC-SQUID that depends on the nature of the qubit state. For flux qubits, the flux magnitude generated by the qubit depends on the flux biasing of the qubit itself, being 0 at the qubit symmetry point Φ_{qb}=Φ₀/2, and positive/negative for fluxes below/above Φ₀. This statement is true, modulo Φ₀.

As the DC-SQUID is placed in a resonant circuit with its capacitor, its degree of freedom, the external superconducting phase difference φ, acquires vacuum fluctuations since it becomes a quantum operator \hat{φ}, besides a constant offset provided by the external current in the above equation for the supercurrent through the DC-SQUID. This means that the SQUID total phase will be given by a constant term and the term containing the quantum fluctuations φₜₒₜ=φ_{DC}+\hat{φ}_{SQ}. The constant term φ_{DC} is given by the supercurrent equation when an external bias current is applied, I_{DC}. This current may be induced by placing the DC-SQUID in an inductive loop that is threaded by an external control flux, e.g. generated by flux generating circuit 11. The resonance frequency of the DC-SQUID resonator is then given by:

$${ω}_{SQ} = \frac{1}{\sqrt{L C}} ,$$

where L may include both Josephson inductance Ly as well as stray geometric inductance L_{S}.

The flux through the SQUID may also be composed of an externally applied static flux φ_{DC} and the flux coming from the qubit Φ_{q}, Φₜₒₜ=Φ_{q}+Φ_{DC}. The flux from the qubit is expressed as Φ_{q}=MÎ, where M is the qubit-SQUID mutual inductance and Î is the persistent current operator of the qubit that has eigenvalues +I and −I corresponding to clockwise and counter-clockwise currents. In the two-level basis, this operator may be expressed as Î=Iₚ [symbol] , with Iₚ the magnitude of the persistent current.

Using realistic device parameters, |Φ_{g}|<<Φ₀ and | [symbol] |<<π. We can then plug in Φₜₒₜ and φₜₒₜ in the SQUID potential energy and expand it to second order in φ_{SQ}. We can also express the [symbol] operator in the basis of resonator operators of creation and annihilation, â and [symbol] :

$$\hat{φ} = ( \frac{2 π}{{Φ}_{0}} ) \sqrt{\frac{ℏ Z}{2}} ( â + ) ,$$

wherein Z=\sqrt{L/C}=ω_{SQ}L is the SQUID impedance. C is formed by both the SQUID junction capacitances as well as any external shunting capacitor (they all add up since they are in parallel).

In a symmetric SQUID, the linear and quadratic interaction terms become (as shown from Felicetti, Physical Review A 97 (1), 013851 (2018):

$${U}_{1} = - 4 {{E}_{J} ( \frac{π}{{Φ}_{0}} )}^{2} sin ( π \frac{{Φ}_{D C}}{{Φ}_{0}} ) sin ( {φ}_{D C} ) {MI}_{p} \sqrt{\frac{{ℏω}_{SQ} L}{2}} ( â + ) , {U}_{2} = - 4 {{E}_{J} ( \frac{π}{{Φ}_{0}} )}^{3} sin ( π \frac{{Φ}_{D C}}{{Φ}_{0}} ) cos ( {φ}_{D C} ) {MI}_{p} \frac{{ℏω}_{SQ} L}{2} {( â + )}^{2} .$$

When no current is applied, φ_{DC}=0 and U2 becomes

$${U}_{2} ( {I}_{s} = 0 ) = - \frac{π}{4} tan ( π \frac{{Φ}_{D C}}{{Φ}_{0}} ) \frac{{MI}_{p}}{{Φ}_{0}} {{ℏω}_{SQ} ( â + )}^{2} {σ}_{z} .$$

If we expand the square, we obtain a term with the dispersive form g₂ [symbol] âσ_{z} with:

$${g}_{2} = - \frac{π}{2} tan ( π \frac{{Φ}_{D C}}{{Φ}_{0}} ) {ℏω}_{SQ} \frac{{MI}_{p}}{{Φ}_{0}} .$$

This term is identical to the calculated symmetric SQUID resonator in equation A indicated above showing a direct connection between the qubit-SQUID physics and the resonator sensitivity in its frequency response.

In reference {Phys. Rev. B 80, 052506 (2009)}, it was shown that the current biasing an asymmetric SQUID is given by:

$${I}_{a c t} = {I}_{C} ( {Φ}_{c o} ) sin ( {φ}_{SQ} - α ( {Φ}_{c o} ) ) .$$

Then, the application of Φ_{act} on the biasing loop determines the SQUID bias phase φ_{SQ}=φ_{DC} from:

$$\frac{{Φ}_{0}}{2 π {L}_{a c t}} ( φ - 2 π {f}_{a c t} ) + {I}_{C} ( {Φ}_{c o} ) sin [ {φ}_{SQ} - α ( {Φ}_{c o} ) ] = 0 ,$$

with f_{act}=2πΦ_{act}/Φ₀.

This relation shows that the two fluxes Φ_{act} and Φ_{co} set the SQUID bias. In the embodiment of FIG. 3, this method can be used for current biasing the DC-SQUID to a desired point to maximize the qubit current readout efficiency.

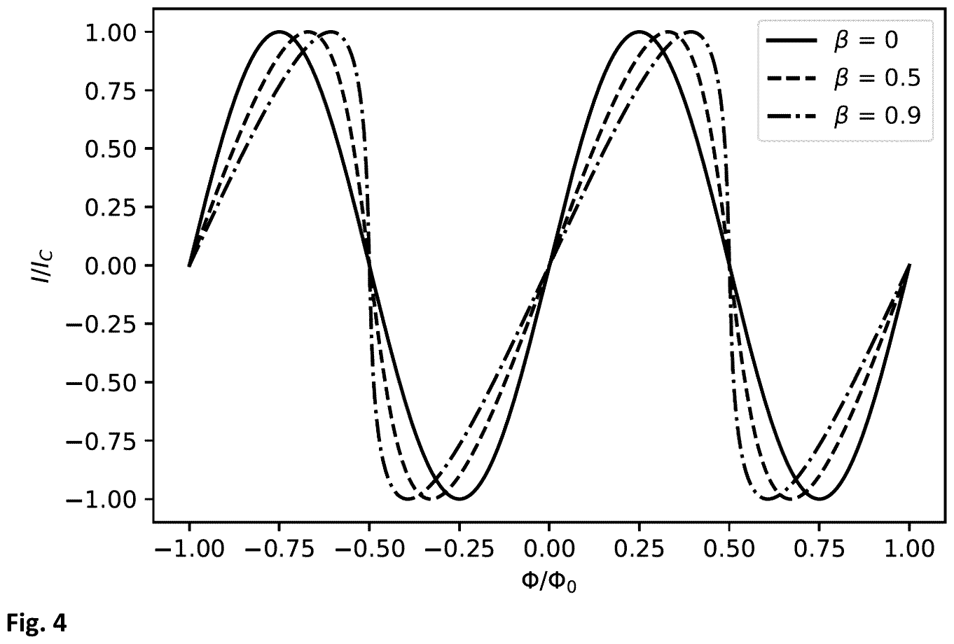

FIG. 4 is a graph showing biasing current flowing into the DC-SQUID (normalized to the DC-SQUID critical current) against the flux threading the second superconducting loop 17, for three different values of the flux threading the DC-SQUID Φ_{SQ}=βΦ₀, wherein β is the ratio between the geometric loop inductance and the effective inductance from the DC-SQUID junctions. The graph thus shows that by controlling the flux threading the second superconducting loop 17, the current bias flowing through the DC-SQUID 16 can be controlled.

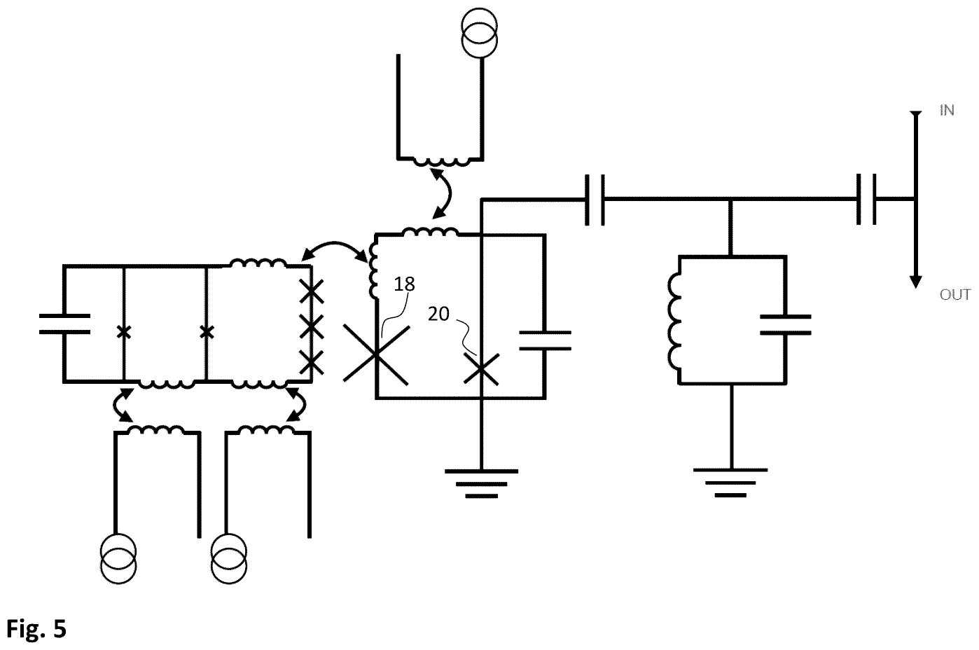

The embodiment of FIG. 5 is similar as the embodiment in FIG. 1. For clarity, reference numbers are not shown again. However, in this embodiment, the first Josephson junction 18 has a first critical current value and the second Josephson junction 20 has a second critical current value that is different from the first critical current value. Typically, the difference in critical current values is in the range of 20%-60%, preferably, in the 30%-50% range. Herein difference may be taken as (the absolute value of) (I₁−I₂)/I₁ or (I₁−I₂)/I₂, wherein I₁ and I₂ indicate the critical current values of the first resp. second Josephson junction. Also, typically, the critical current values are in the micro ampere range. Such a DC-SQUID may be referred to as an asymmetric DC-SQUID (a DC-SQUID having two identical Josephson junctions may be referred to as a symmetric DC-SQUID). In the depicted embodiment Josephson junction 18 has a higher critical current value than Josephson junction 20, as indicated by the larger cross.

The critical current of the asymmetric DC-SCQUID is given by:

$${I}^{A} ( Φ ) = \sqrt{{I}_{1}^{2} + {I}_{2}^{2} + 2 {I}_{1} {I}_{2} cos ( 2 π f )} ,$$

wherein I₁ is the critical current of the first Josephson junction and I₂ the critical current of the second Josephson junction.

Rewriting it as I₁=I_{C} and I₂=βI_{C}:

$${I}^{A} ( Φ ) = {I}_{C} \sqrt{1 + {β}^{2} + 2 β cos ( 2 π f )} .$$

The potential energy of the asymmetric DC-SQUID has the following form

$$U = \frac{{I}^{A} ( Φ ) {Φ}_{0}}{2 π} cos ( φ - α ( Φ ) ) ,$$

with

$$α ( Φ ) = - arctan [ tan ( π f ) \frac{1 - β}{1 + β} ] .$$

This means that there is a finite phase offset due to the asymmetry. As a consequence, the supercurrent through the DC-SQUID is given by:

$$I = {I}^{A} ( Φ ) sin ( φ - α ( Φ ) ) .$$

The Josephson inductance becomes

$${L}_{J}^{A} = \frac{{Φ}_{0}}{2 π {I}^{A} ( Φ ) cos ( {φ}_{D C} - α ( Φ ) )} .$$

This expression shows that the inductance is influenced by the α(Φ) term, which is due to the asymmetry. Thus, the asymmetry causes a flux-sensitive phase offset to the inductance. This enhances the flux sensitivity of the inductance to changes in flux coming from a qubit, as now both the critical current part and the phase offset part change with flux.

The asymmetry of the DC-SQUID may be understood to enable the effective transfer of information from the internal degree of freedom of the SQUID, which is the phase difference between the two junctions and corresponds to the circulating current flowing around the loop that is inductively coupled to the flux qubit, to an effective bias current applied across the SQUID.

In FIG. 6, the change of resonance frequency of the DC-SQUID resonator detector (normalized to the frequency with no applied external flux) as function of the externally applied magnetic flux (normalized to the flux quantum) is shown. The frequency is normalized to the value at the maximum frequency corresponding to no flux applied. The two operation points of the detector during qubit operation are indicated.

When an algorithm is executed (annealing is performed), the DC-SQUID resonator may be biased at Φ=0 where the sensitivity of the DC-SQUID to flux vanishes, to first order (the first derivative of the frequency with respect to flux, which is the SQUID sensitivity, is zero for integer of flux quanta,

$$\frac{Φ}{{Φ}_{0}} = N ,$$

N being an integer). In this setting, the SQUID is set in the “OFF” state. This implies that the DC-SQUID does not sense any flux from the qubit, and, vice-versa, the DC-SQUID produces no flux into the qubit. Therefore, the qubit is effectively decoupled from the SQUID resonator at this flux operation point. This will prevent noise coming from the readout lines connected to the SQUID not reaching the qubit, hence keeping its coherence time as long as possible.

Once the algorithm is finished (annealing finished), a flux signal may sent to the SQUID to set it in an operation point to perform the readout. In this setting, the SQUID is in the “ON” state. At this flux bias point, the SQUID is sensitive to flux (the derivative of the frequency to external flux in the SQUID is finite) and therefore the SQUID senses the additional flux generated by the qubit. The readout operation of the qubit current state needs to be performed fast enough to avoid noise coming from the SQUID readout line to affect the qubit coherence. This guarantees maximum readout visibility.

Preferably, the change in resonance frequency due to changes in flux is relatively large, because this will cause the transmitted/reflected probe signal to have quite large phase shifts with respect to the provided probe. This is in part due to the fact that the quality factor of the DC-SQUID resonator is high (in the 1000-5000 range) leading to observable frequency shifts when qubit flux changes sign.

Preferably, the flux generating circuit 10 is able to generate flux as large as Φ₀/2 because this causes a flux through the DC-SQUID close to Φ/Φ₀=0.50. This requires current values in the flux generating circuit 10 of a few mA.

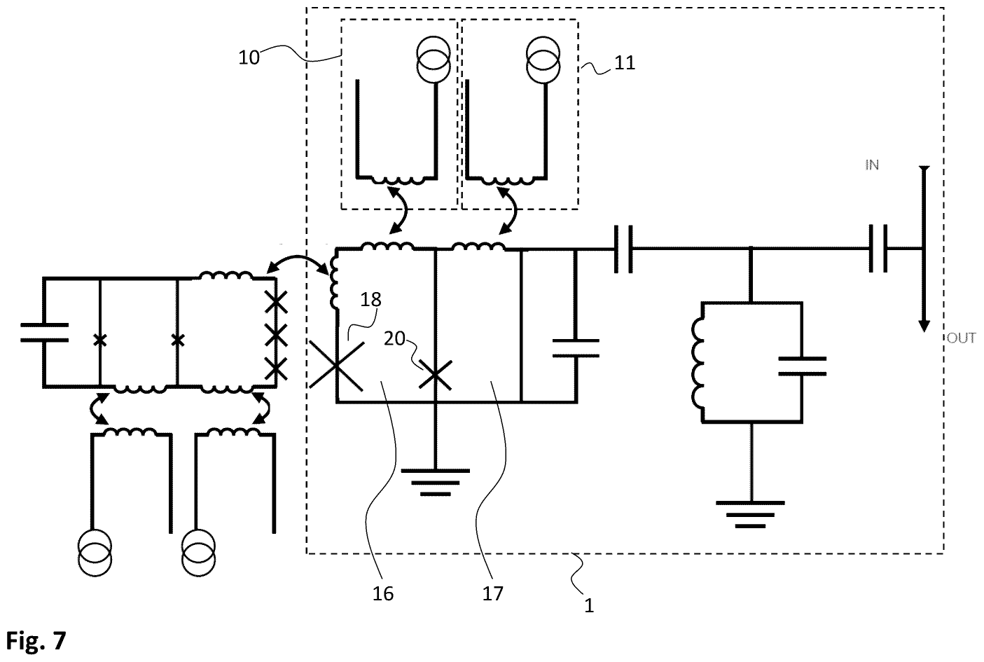

FIG. 7 is an embodiment wherein the system comprises an asymmetric DC-SQUID and a second superconducting loop 17.

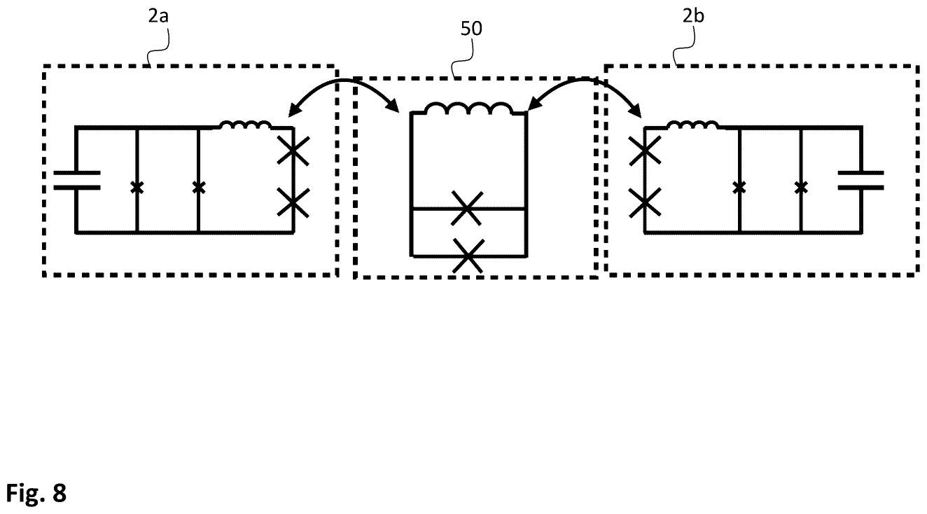

FIG. 8 illustrates a coupler circuit 50 that is configured to couple two flux qubits 2a and 2b together.

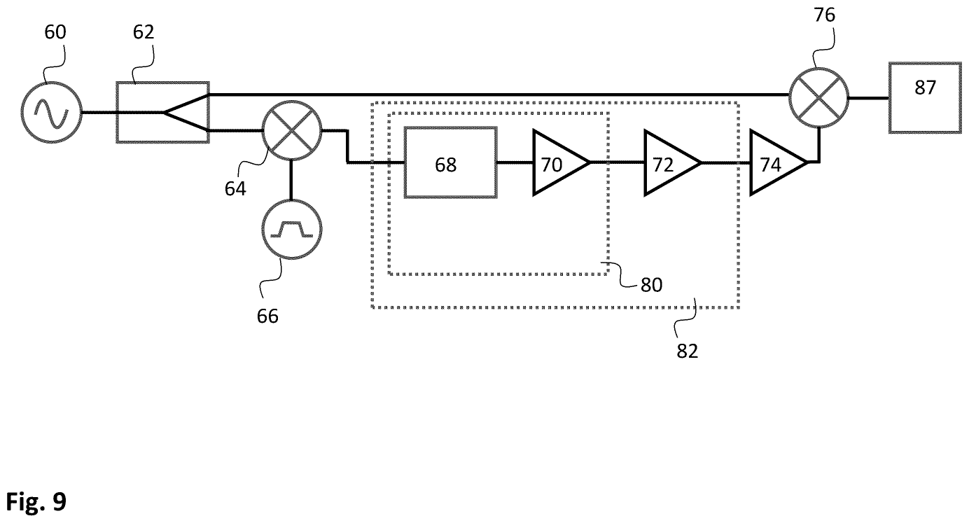

FIG. 9 illustrates a system for measuring a direction of current in a flux qubit according to an embodiment. The flux qubit, resonator circuit, and optional bandpass filter are indicted in this figure as a system 68.

The depicted embodiment comprise a probe signal generator 60 that is configured to generate a signal having an appropriate frequency and power. The generated signal is fed to a splitter system 62 that is configured to split the generated signal into a first copy and a second copy of the generated signal. The first copy is provided to a mixer 64 that is configured to combine the generated signal with a signal (pulse) generated by a signal pulse generator 66 that is frequency upconverted by the mixer 64. Mixer 64 then output the probe signal that is provided to the resonator circuit (not shown) in order to probe the resonance frequency of the resonator circuit. Preferably, the probe signal passes through a bandpass filter described herein before being provided to the resonator circuit so that a clean probe signal (without noise signal components) is provided to the resonator circuit. In any case, the reflected/transmitted probe signal is then input to a quantum limited amplifier 70 that is configured to amplify the reflected/transmitted probe signal with the addition of the minimum amount of noise as given by quantum mechanics. Then, the amplified signal is, in this embodiment, amplified twice by two respective low-noise amplifiers 72 and 74. Thereafter, the reflected/transmitted probe signal is combined again, in mixer 76 with the second copy of the signal generated by the generator 60 in order to downconvert the reflected/transmitted probe signal for measuring the transmitted/reflected probe signal with an analog to digital converter 87 so that (a downconverted version of) the reflected/transmitted probe signal can be digitized, stored and further analyzed.

As shown, the system 68 and the amplifier 70 are present in box 80, which indicates a millikelvin stage of a cryostat environment, whereas low noise amplifier 72 is present in box 82 which indicates a 4 Kelvin stage of the cryostat environment.

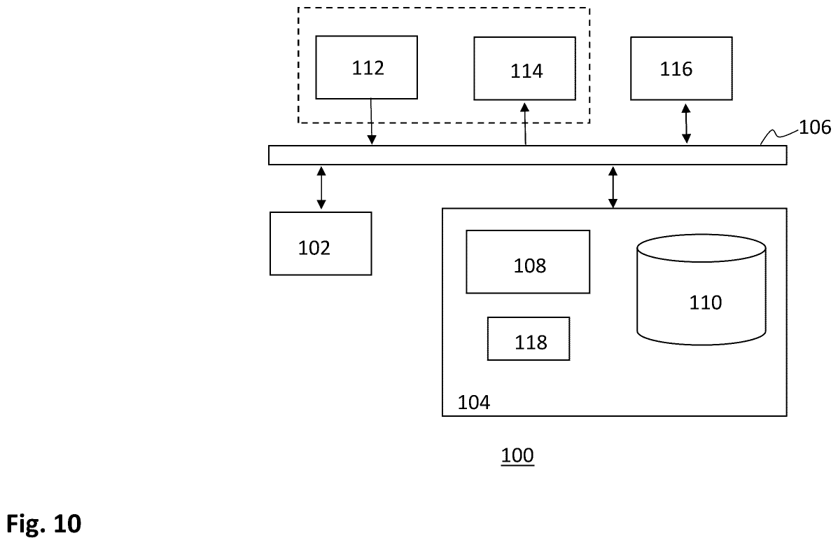

FIG. 10 depicts a block diagram illustrating a data processing system according to an embodiment.

As shown in FIG. 10, the data processing system 100 may include at least one processor 102 coupled to memory elements 104 through a system bus 106. As such, the data processing system may store program code within memory elements 104. Further, the processor 102 may execute the program code accessed from the memory elements 104 via a system bus 106. In one aspect, the data processing system may be implemented as a computer that is suitable for storing and/or executing program code. It should be appreciated, however, that the data processing system 100 may be implemented in the form of any system including a processor and a memory that is capable of performing the functions described within this specification.

The memory elements 104 may include one or more physical memory devices such as, for example, local memory 108 and one or more bulk storage devices 110. The local memory may refer to random access memory or other non-persistent memory device(s) generally used during actual execution of the program code. A bulk storage device may be implemented as a hard drive or other persistent data storage device. The processing system 100 may also include one or more cache memories (not shown) that provide temporary storage of at least some program code in order to reduce the number of times program code must be retrieved from the bulk storage device 110 during execution.

Input/output (I/O) devices depicted as an input device 112 and an output device 114 optionally can be coupled to the data processing system. Examples of input devices may include, but are not limited to, a keyboard, a pointing device such as a mouse, a touch-sensitive display, or a probe line 19 that conducts and inputs the transmitted/reflected probe signal, or the like. Examples of output devices may include, but are not limited to, a monitor or a display, speakers, a probe line 19 that conducts a probe signal to the resonator circuit 8, or the like. Input and/or output devices may be coupled to the data processing system either directly or through intervening I/O controllers.

In an embodiment, the input and the output devices may be implemented as a combined input/output device (illustrated in FIG. 10 with a dashed line surrounding the input device 112 and the output device 114). An example of such a combined device is a touch sensitive display, also sometimes referred to as a “touch screen display” or simply “touch screen”. In such an embodiment, input to the device may be provided by a movement of a physical object, such as e.g. a stylus or a finger of a user, on or near the touch screen display.

A network adapter 116 may also be coupled to the data processing system to enable it to become coupled to other systems, computer systems, remote network devices, and/or remote storage devices through intervening private or public networks. The network adapter may comprise a data receiver for receiving data that is transmitted by said systems, devices and/or networks to the data processing system 100, and a data transmitter for transmitting data from the data processing system 100 to said systems, devices and/or networks. Modems, cable modems, and Ethernet cards are examples of different types of network adapter that may be used with the data processing system 100.

As pictured in FIG. 10, the memory elements 104 may store an application 118. In various embodiments, the application 118 may be stored in the local memory 108, the one or more bulk storage devices 110, or apart from the local memory and the bulk storage devices. It should be appreciated that the data processing system 100 may further execute an operating system (not shown in FIG. 10) that can facilitate execution of the application 118. The application 118, being implemented in the form of executable program code, can be executed by the data processing system 100, e.g., by the processor 102. Responsive to executing the application, the data processing system 100 may be configured to perform one or more operations or method steps described herein.

In one aspect of the present invention, the data processing system 100 may represent a measurement system or signal analysis system as described herein.

Various embodiments of the invention may be implemented as a program product for use with a computer system, where the program(s) of the program product define functions of the embodiments (including the methods described herein). In one embodiment, the program(s) can be contained on a variety of non-transitory computer-readable storage media, where, as used herein, the expression “non-transitory computer readable storage media” comprises all computer-readable media, with the sole exception being a transitory, propagating signal. In another embodiment, the program(s) can be contained on a variety of transitory computer-readable storage media. Illustrative computer-readable storage media include, but are not limited to: (i) non-writable storage media (e.g., read-only memory devices within a computer such as CD-ROM disks readable by a CD-ROM drive, ROM chips or any type of solid-state non-volatile semiconductor memory) on which information is permanently stored; and (ii) writable storage media (e.g., flash memory, floppy disks within a diskette drive or hard-disk drive or any type of solid-state random-access semiconductor memory) on which alterable information is stored. The computer program may be run on the processor 102 described herein.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of embodiments of the present invention has been presented for purposes of illustration, but is not intended to be exhaustive or limited to the implementations in the form disclosed. Many modifications and variations will be apparent to those of ordinary skill in the art without departing from the scope and spirit of the present invention. The embodiments were chosen and described in order to best explain the principles and some practical applications of the present invention, and to enable others of ordinary skill in the art to understand the present invention for various embodiments with various modifications as are suited to the particular use contemplated.

1. A method for measuring a direction of current in a flux qubit, the method comprising
providing a probe signal to a resonator circuit, the resonator circuit having a resonance frequency, the probe signal transmitting through or reflecting from the resonator circuit, wherein the resonator circuit comprises a DC SQUID comprising a first superconducting loop interrupted by a first Josephson junction and by a second Josephson junction, the first Josephson junction and second Josephson junction being connected in parallel and the first superconducting loop of the DC SQUID being directly coupled to the flux qubit via inductive coupling;
measuring the reflected probe signal that has reflected from the resonator circuit or, respectively, measuring the transmitted probe signal that has transmitted through the resonator circuit; and,
determining the direction of current in the flux qubit based on a difference, such as a phase difference, between the provided probe signal and the reflected probe signal or, respectively, between the provided probe signal and the transmitted probe signal.

2. The method according to claim 1 wherein the resonator circuit is controlled to be in a first state or in a second state, preferably based on a first flux signal or a second flux signal respectively, wherein in the first state the resonator circuit is insensitive to small flux variations so that it decouples from the flux qubit and wherein in the second state the resonator circuit is sensitive to small flux variations so that it is coupled to the flux qubit for determining the direction of the current in the flux qubit.

3. The method according to claim 1, wherein the method further comprises: using a flux generating circuit that is inductively coupled to the first superconducting loop of the resonator circuit, providing a magnetic flux to the first superconducting loop herewith controlling the resonant frequency of the resonator circuit; and/or, wherein the first Josephson junction has a first critical current value and the second Josephson junction has a second critical current value, wherein the first critical current value is equal to the second critical current value or wherein the first critical current value is different from the second critical current value.

4. The method according to claim 1, wherein
the resonator circuit comprises a second superconducting loop that is interrupted by the second Josephson junction, the method comprising
using a second flux generating circuit that is inductively coupled to the second superconducting loop of the resonator circuit, to provide a magnetic flux to the second superconducting loop for biasing the first superconducting loop with a bias current, preferably to provide a first magnetic flux value to the second superconducting loop so that the resonator circuit is insensitive to small flux variations and therefore decouples from the flux qubit, while the flux qubit is being operated, or to provide a second flux value to the second superconducting loop so that the resonator circuit is sensitive to small flux variations when a current direction of the flux qubits needs to be determined.

5. The method according to claim 1, wherein
due to an inductive coupling between the first superconducting loop and the flux qubit, the resonant frequency of the resonator circuit has a first value when the current in the flux qubit has a first direction, e.g. a clockwise direction, and has a second value, different from the first value, when the current in the flux qubit has a second direction, e.g. a counter-clockwise direction, and wherein
the probe signal provided to the resonator circuit has a frequency lower than the first or second value and higher than the second or, respectively, first value.

6. The method according to claim 1, wherein
the probe signal is provided to the resonator circuit via a probe line, the method comprising
preventing noise signals arriving via the probe line from reaching the resonator circuit using a bandpass filter, such as a resonator filter.

7. The method according to claim 6, further comprising
after bandpass filtering the reflected or transmitted probe signal, amplifying the reflected or transmitted probe signal using a quantum-limited amplifier, such as a traveling-wave parametric amplifier.

8. A system for measuring a direction of current in a flux qubit comprising:
a resonator circuit having a resonance frequency, the resonator circuit comprises a DC SQUID comprising a first superconducting loop interrupted by a first Josephson junction and by a second Josephson junction, the first Josephson junction and second Josephson junction being connected in parallel and the first superconducting loop a of the DC SQUID being directly coupled to the flux qubit via inductive coupling;
a probe signal provisioning system for providing a probe signal to the resonator circuit such that the probe signal transmits through or reflects from the resonator circuit;
a measurement system for measuring the reflected probe signal that has reflected from the resonator circuit or, respectively, for measuring the transmitted probe signal that has transmitted through the resonator circuit; and,
a signal analysis system for determining a difference between the provided probe signal and the reflected probe signal or, respectively, between the provided probe signal and the transmitted probe signal.

9. The system according to claim 8, further comprising a flux generating circuit that is inductively coupled to the first superconducting loop of the resonator circuit and that is configured to provide a magnetic flux to the first superconducting loop for controlling the resonant frequency of the resonator circuit.

10. The system according to claim 8, wherein the first Josephson junction has a first critical current and the second Josephson junction has a second critical current that may be different from the first critical current.

11. The system according to claim 8, wherein
the resonator circuit comprises a second superconducting loop that is interrupted by the second Josephson junction, the system further comprising
a second flux generating circuit that is inductively coupled to the second superconducting loop of the resonator circuit, and that is configured to provide a magnetic flux to the second superconducting loop, preferably that is configured to provide a first magnetic flux value to the second superconducting loop so that the resonator circuit is insensitive to flux and therefore decouples from the flux qubit, while the flux qubit is being operated, or to provide a second flux value to the second superconducting loop so that the resonator circuit is sensitive to flux when the current direction of the flux qubits needs to be determined.

12. The system according to claim 8, further comprising
a bandpass filter, preferably a resonator filter, that is configured to prevent noise signals, that come from a probe line via which the probe signal is provided to the resonator circuit, from reaching the resonator circuit.

13. The system according to claim 8, further comprising
a quantum-limited amplifier that is configured to amplify the transmitted or reflected probe signal.

14. The system according to claim 8, wherein
at least part of the system is in a cryogenic environment and wherein said at least part of the system in the cryogenic environment does not comprise a resistor.

15. The system according to claim 8, further comprising a data processing system that is configured to, based on the difference between the probe signal and the reflected probe signal or, respectively, between the probe signal and the transmitted probe signal, such as a phase difference, determining the current direction in the flux qubit.
